(19) United States
(12) Patent Application Publication
(10) Pub. No.: US 2021/0151502 A1
(43) Pub. Date: May 20, 2021

(54) MAGNETORESISTIVE RANDOM ACCESS MEMORY DEVICE AND EMBEDDED DEVICE

(71) Applicant: SAMSUNG ELECTRONICS CO., LTD., Suwon-si (KR)

(72) Inventors: Woojin KIM, Hwaseong-si (KR); Yongjae KIM, Seongnam-si (KR); Kilho LEE, Busan (KR)

(21) Appl. No.: 16/892,583

(22) Filed: Jun. 4, 2020

(30) Foreign Application Priority Data
Nov. 20, 2019 (KR) 10-2019-0149919

(51) Int. Cl. H01L 27/22; G11C 11/16; H01L 43/02

(52) U.S. Cl. CPC H01L 27/222; H01L 43/02; G11C 11/161

(57) ABSTRACT

A magnetoresistive random access memory device including a first insulating interlayer on a substrate; lower electrode contacts passing through the first insulating interlayer; first structures on the lower electrode contacts, respectively, each of the first structures including a stacked lower electrode, magnetic tunnel junction (MTJ) structure, and upper electrode; a second insulating interlayer on the first structures and the first insulating interlayer, the second insulating interlayer filling a space between the first structures; a third insulating interlayer directly contacting the second insulating interlayer, the third insulating interlayer having a dielectric constant lower than a dielectric constant of the second insulating interlayer; and a bit line passing through the third insulating interlayer and the second insulating interlayer, the bit line contacting the upper electrode of one of the first structures.

### CROSS-REFERENCE TO RELATED APPLICATION

Korean Patent Application No. 10-2019-0149919, filed on Nov. 20, 2019, in the Korean Intellectual Property Office, and entitled: “Magnetoresistive Random Access Memory Device and Embedded Device,” is incorporated by reference herein in its entirety.

### BACKGROUND

### 1. Field

Embodiments relate to a magnetoresistive random access memory (MRAM) device and an embedded device.

### 2. Description of the Related Art

An MRAM device may include a stacked structure including an MTJ structure, an upper electrode, and a bit line electrically connected to the upper electrode.

### SUMMARY

The embodiments may be realized by providing a magnetoresistive random access memory device including a first insulating interlayer on a substrate; lower electrode contacts passing through the first insulating interlayer; first structures on the lower electrode contacts, respectively, each of the first structures including a stacked lower electrode, magnetic tunnel junction (MTJ) structure, and upper electrode; a second insulating interlayer on the first structures and the first insulating interlayer, the second insulating interlayer filling a space between the first structures; a third insulating interlayer directly contacting the second insulating interlayer, the third insulating interlayer having a dielectric constant lower than a dielectric constant of the second insulating interlayer; and a bit line passing through the third insulating interlayer and the second insulating interlayer, the bit line contacting the upper electrode of one of the first structures.

The embodiments may be realized by providing a magnetoresistive random access memory device including a lower insulating interlayer and a lower wiring on a substrate; a first insulating interlayer on the lower insulating interlayer and the lower wiring; lower electrode contacts passing through the first insulating interlayer; first structures on the lower electrode contacts, respectively, each of the first structures including a stacked lower electrode, magnetic tunnel junction (MTJ) structure, and upper electrode stacked; a capping layer covering an upper surface of the first insulating interlayer and surfaces of the first structures; a second insulating interlayer on the capping layer, the second insulating interlayer including an oxide and filling a space between the first structures; a third insulating interlayer directly contacting the second insulating interlayer, the third insulating interlayer including an oxide having a dielectric constant lower than that of the second insulating interlayer; and a bit line passing through the third insulating interlayer, the second insulating interlayer, and the capping layer, the bit line contacting the upper electrode of one of the first structures; wherein the upper surface of the first insulating interlayer between the first structures includes a recess, surfaces of the recess being closer to the substrate in a vertical direction than a plane of lower surfaces of the first structures is to the substrate in the vertical direction.

The embodiments may be realized by providing an embedded device including a substrate including a first region and a second region; a first insulating interlayer on the substrate; lower electrode contacts passing through the first insulating interlayer on the first region; first structures on the lower electrode contacts, respectively, each of the first structures including a stacked lower electrode, magnetic tunnel junction (MTJ) structure, and upper electrode; a capping layer covering an upper surface of the first insulating interlayer and surfaces of the first structures on the first region and the second region; a second insulating interlayer on the capping layer, the second insulating interlayer including an oxide and filling a space between the first structures; a third insulating interlayer directly contacting the second insulating interlayer, the third insulating interlayer including an oxide having a dielectric constant lower than that of the second insulating interlayer; a bit line passing through the third insulating interlayer and the second insulating interlayer on the first region, the bit line contacting the upper electrode of one of the first structures; and a via contact passing through the third insulating interlayer, the second insulating interlayer, the capping layer, and the first insulating interlayer on the second region.

### BRIEF DESCRIPTION OF THE DRAWINGS

Features will be apparent to those of skill in the art by describing in detail exemplary embodiments with reference to the attached drawings in which:

FIG. 1 is a cross-sectional view of an MRAM device in accordance with example embodiments;

FIG. 2 is a cross-sectional view of an MRAM device in accordance with example embodiments;

FIGS. 3 to 12 are cross-sectional views of stages in a method of manufacturing an MRAM device in accordance with example embodiments;

FIG. 13 is a cross-sectional view of an embedded device including an MRAM device and a logic device in accordance with example embodiments; and

FIGS. 14 to 18 are cross-sectional views of stages in a method of manufacturing an embedded device including an MRAM device and a logic device in accordance with example embodiments.

### DETAILED DESCRIPTION

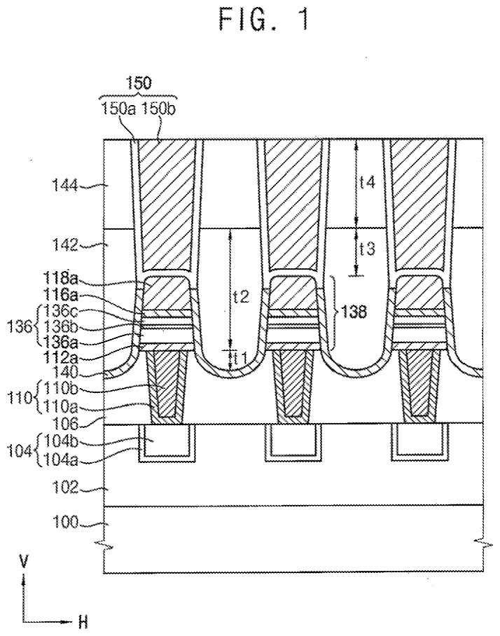

FIG. 1 is a cross-sectional view of an MRAM device in accordance with example embodiments.

Referring to FIG. 1, the MRAM device may be on a substrate 100. The MRAM device may include a first insulating interlayer 106, a lower electrode contact 110, a lower electrode 112a, a magnetic tunnel junction (MTJ) structure 136, a middle electrode 116a, and an upper electrode 118a. In an implementation, the MRAM device may include a capping layer 140, a second insulating interlayer 142, a third insulating interlayer 144, and a bit line 150. The MRAM device may further include a lower insulating interlayer 102 and a lower wiring 104.

The substrate 100 may include silicon, germanium, silicon-germanium, or a group III-V compound such as GaP, GaAs, GaSb, or the like. In an implementation, the substrate 100 may be a silicon-on-insulator (SOI) substrate or a germanium-on-insulator (GOI) substrate. As used herein, the term “or” is not an exclusive term, e.g., “A or B” would include A, B, or A and B.

Circuit patterns may be on the substrate 100. The lower insulating interlayer 102 may be on the substrate 100 to cover the circuit patterns.

In an implementation, the circuit patterns may include a transistor, a wiring, or the like. The lower insulating interlayer 102 may include silicon oxide.

A plurality of lower wirings 104 may be inside and on the lower insulating interlayer 102.

In an implementation, upper surfaces (e.g., surfaces facing away from the substrate 100 in a vertical direction V) of ones of the lower wirings 104 may be coplanar with an upper surface of the lower insulating interlayer 102. In an implementation, the upper surfaces of ones of the lower wirings 104 may be exposed at the upper surface of the lower insulating interlayer 102. The lower wiring 104 may include a barrier metal pattern 104a and a metal pattern 104b. The barrier metal pattern 104a may include, e.g., a metal nitride such as tungsten nitride, tantalum nitride, titanium nitride, or a metal such as tantalum, titanium, or the like. The metal pattern 104b may include, e. g., tungsten, copper, aluminum, or the like.

The first insulating interlayer 106 may be on the lower wiring 104 and the lower insulating interlayer 102. The first insulating interlayer 106 may include silicon oxide.

The lower electrode contact 110 may pass through the first insulating interlayer 106, and may contact the upper surface of the lower wiring 104. In an implementation, an etch stop layer may be further included between the lower insulating interlayer 102 and the first insulating interlayer 106.

In an implementation, the lower electrode contact 110 may include a first barrier pattern 110a and a first conductive pattern 110b. The first barrier pattern 110a may include, e.g., a metal nitride such as tungsten nitride, tantalum nitride, titanium nitride, and/or a metal such as tantalum, titanium, or the like. The first conductive pattern 110b may include a metal having a low resistance, such as tungsten, copper, aluminum, or the like.

A first structure 138 may be on the lower electrode contact 110. The first structure 138 may have a pillar shape in which the lower electrode 112a, the MTJ structure 136, the middle electrode 116a, and the upper electrode 118a may be sequentially stacked.

In an implementation, in the first structure 138, the middle electrode 116a may be omitted.

In an implementation, a sidewall of the first structure 138 may be inclined such that a width (e.g., as measured in a horizontal direction H) of the first structure 138 may be decreased downwardly (e.g., in the vertical direction V). In an implementation, the sidewall of the first structure 138 may have a vertical slope (e.g., may not be inclined).

In an implementation, the first structure 138 may also be on the first insulating interlayer 106 adjacent to the lower electrode contact 110 to completely cover the upper surface of the lower electrode contact 110.

An upper surface of the first insulating interlayer 106 between the first structures 138 may be lower (e.g., closer to the substrate 100 in the vertical direction V) than a lower surface (e.g., substrate 100-facing surface) of the first structure 138. In an implementation, the upper surface of the first insulating interlayer between the first structures 138 may include a recess lower than the lower surface of the first structures 138 (e.g., a lowermost point of the recess may be closer to the substrate 100 in the vertical direction V than a lowermost point of the first structures 138).

The lower electrode 112a may include, e.g., a metal such as titanium or tantalum or a metal nitride such as titanium nitride or tantalum nitride.

The MTJ structure 136 may include a first magnetic pattern 136a, a tunnel barrier pattern 136b, and a second magnetic pattern 136c sequentially stacked (e.g., in the vertical direction V).

In an implementation, the first magnetic pattern 136a may serve as a fixed layer having a fixed magnetization direction. In an implementation, the first magnetic pattern 136a may include a fixed pattern, a lower ferromagnetic pattern, an antiferromagnetic coupling spacer pattern, and an upper ferromagnetic pattern. In an implementation, the fixed pattern may include, e.g., manganese iron (FeMn), manganese iridium (IrMn), manganese platinum (PtMn), manganese oxide (MnO), manganese sulfide (MnS), tellurium manganese (MnTe), manganese fluoride (MnF₂), iron fluoride (FeF₂), iron chloride (FeCl₂), iron oxide (FeO), cobalt chloride (CoCl₂), cobalt oxide (CoO), nickel chloride (NiCl₂), nickel oxide (NiO), chromium (Cr), or the like. Each of the upper ferromagnetic pattern and lower ferromagnetic pattern may include, e.g., a ferromagnetic material including iron (Fe), nickel (Ni), or cobalt (Co). The antiferromagnetic coupling spacer pattern may include, e.g., ruthenium (Ru), iridium (Ir), or rhodium (Rh).

In an implementation, the second magnetic pattern 136c may serve as a free layer having a variable magnetization direction. In this case, the second magnetic pattern 136c may include a ferromagnetic material such as iron (Fe), cobalt (Co), nickel (Ni), chromium (Cr), and platinum (Pt), or the like. The second magnetic pattern 136c may further include boron (B) or silicon (Si). The materials may be used alone or in combination of two or more. In an implementation, the second magnetic pattern 136c may include a composite material such as CoFe, NiFe, FeCr, CoFeNi, PtCr, CoCrPt, CoFeB, NiFeSiB, CoFeSiB, or the like.

The tunnel barrier pattern 136b may be between the first and second magnetic patterns 136a and 136c. Thus, the first and second magnetic patterns 136a and 136c may not directly contact to each other.

In an implementation, the tunnel barrier pattern 136b may include an insulating metal oxide. In an implementation, the tunnel barrier pattern 136b may include magnesium oxide (MgOx) or aluminum oxide (AlOx).

The middle electrode 116a may include a metal such as titanium or tantalum or a metal nitride such as titanium nitride or tantalum nitride.

The upper electrode 118a may include, e.g., tungsten, copper, platinum, nickel, silver, gold, or the like. In an implementation, the upper electrode 118a may include tungsten.

The capping layer 140 may be conformally formed on surfaces of the first structure 138 and the first insulating interlayer 106. The capping layer 140 may have a substantially uniform thickness. The capping layer 140 may contact a sidewall of the first structure 138 to protect the first structure 138. The capping layer 140 may include, e.g., silicon nitride or silicon oxynitride.

An upper surface of the capping layer 140 on the first insulating interlayer 106 may be lower than the lower surface of the first structure 138. That is, the upper surface of the capping layer 140 may include a recess, and thus the recess of the upper surface of the capping layer 140 may be formed by or in the recess of the upper surface of the first insulating interlayer 106. A height of the recess of the capping layer 140 may be defined as a height (in the vertical direction V) from a lowermost portion of an upper surface of the capping layer 140 to a level or plane of the lower surface of the first structure 138. The height of the recess of the capping layer 140 may be referred to as a first height t1.

The second insulating interlayer 142 may be on the capping layer 140. An upper surface of the second insulating interlayer 142 may be substantially flat.

The second insulating interlayer 142 may fill a space between the first structures 138. The second insulating interlayer 142 may include an oxide such as silicon oxide. The second insulating interlayer 142 may have a first dielectric constant. In an implementation, the first dielectric constant may be 3.9 or less.

The second insulating interlayer 142 may include, e.g., a silicon oxide layer formed by a high density plasma (HDP)-CVD process. In the HDP-CVD process, a deposition layer may be formed by repeatedly performing deposition and some etching processes. Thus, when the deposition layer is deposited to a target thickness or more, an upper surface of the deposition layer may have high flatness.

In an implementation, a height t2 (in the vertical direction V) from a plane of the lower surface of the first structure 138 to an upper surface of the second insulating interlayer 142 may be greater than twice the first height t1. In an implementation, the upper surface of the second insulating interlayer 142 may be higher (e.g., farther from the substrate 100 in the vertical direction V) than the upper surface of the first structure 138.

The third insulating interlayer 144 may directly contact the second insulating interlayer 142. The third insulating interlayer 144 may include an oxide formed by a deposition process different from that the deposition process for forming the second insulating interlayer 142.

In an implementation, the third insulating interlayer 144 may include a low dielectric layer. The third insulating interlayer 144 may have a second dielectric constant lower than the first dielectric constant. In an implementation, the third insulating interlayer 144 may have a dielectric constant of about 3.5 or less.

In an implementation, the third insulating interlayer 144 may include a silicon oxide, a fluorinated silicon oxide (SiOF), a carbon doped oxide, or the like. In an implementation, the third insulating interlayer 144 may include a porous oxide.

In an implementation, the third insulating interlayer 144 may have a structure in which a plurality of low dielectric layers may be stacked.

In an implementation, the insulation layers on the capping layer 140 may have dielectric constants lower than that of silicon nitride. In an implementation, an etch stop layer including silicon nitride may not be included between the second insulating interlayer 142 and the third insulating interlayer 144.

In an implementation, a height t4 (in the vertical direction V) of the third insulating interlayer 144 may be higher than a height t3 (in the vertical direction V) of a portion of the second insulating interlayer 142 positioned on a top surface of the first structure 138 (e.g., a portion of the second insulating interlayer 142 that is farther from the substrate 100 in the vertical direction V than the first structure 138).

The bit line 150 may pass through the third insulating interlayer 144, the second insulating interlayer 142, and the capping layer 140, and the bit line 150 may contact the upper electrode 118a. The bit line 150 may extend lengthwise in a direction parallel to the upper surface of the substrate 100. A bottom surface of the bit line 150 may contact a plurality of the upper electrodes 118a that are arranged (e.g., spaced apart) in the direction parallel to the upper surface of the substrate 100.

In an implementation, the bit line 150 may contact an upper surface and an upper sidewall of the upper electrode 118a. In this case, the capping layer 140 may not be on the upper surface and the upper sidewall of the upper electrode 118a. A lowermost surface of the bit line 150 may be lower (e.g., closer to the substrate 100 in the vertical direction V) than the upper surface of the upper electrode 118a. In an implementation, the upper electrode 118a may protrude from the lowermost surface of the bit line 150 (e.g., in the vertical direction V).

In an implementation, a lower width of the bit line 150 may be greater than a top width of the upper electrode 118a (e.g., as measured in the horizontal direction H).

The bit line 150 may include a second barrier pattern 150a and a second metal pattern 150b.

The second barrier pattern 150a may include, e.g., a metal nitride such as tungsten nitride, tantalum nitride, titanium nitride, and/or a metal such as tantalum, titanium, or the like. The second metal pattern 150b may include a metal having a low resistance, such as tungsten, copper, aluminum, or the like.

The second insulating interlayer 142 and the third insulating interlayer 144 including a silicon oxide may be between the bit lines 150. In an implementation, an etch stop layer including silicon nitride may not be formed between the bit lines 150.

As such, an insulation material having a dielectric constant higher than that of silicon oxide may not be formed between the bit lines 150. Also, the third insulating interlayer 144 having a low dielectric constant may be formed between the bit lines 150. Thus, a parasitic capacitance between the bit lines 150 may be decreased, even if a distance between the bit lines 150 is reduced.

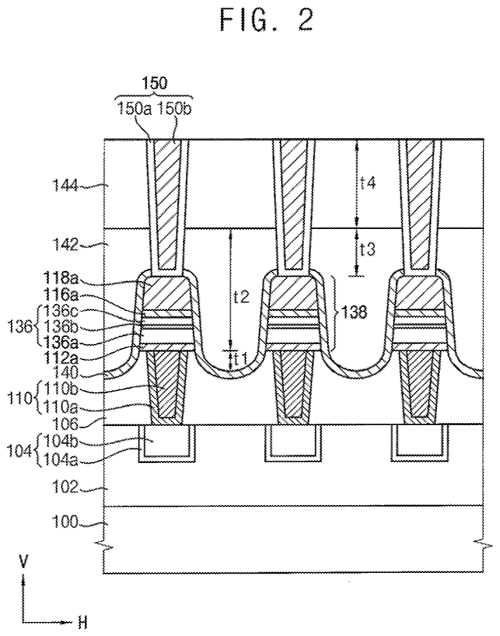

FIG. 2 is a cross-sectional view of an MRAM device in accordance with example embodiments.

The MRAM device shown in FIG. 2 may be substantially the same as the MRAM device shown in FIG. 1, except for a shape of the bit line. Therefore, the bit line may be mainly described.

Referring to FIG. 2, the bit line 150 may contact an upper surface of the upper electrode 118a. In an implementation, the capping layer 140 may not be formed on (e.g., all of) the upper surface of the upper electrode 118a. The capping layer 140 may cover a sidewall of the first structure 138 and the first insulating interlayer 106.

In an implementation, a bottom surface of the bit line 150 may be substantially coplanar with a top surface of the upper electrode 118a.

In an implementation, a lower width (e.g., as measured in the horizontal direction H) of the bit line 150 may be equal to or less than a top width of the upper electrode 118a.

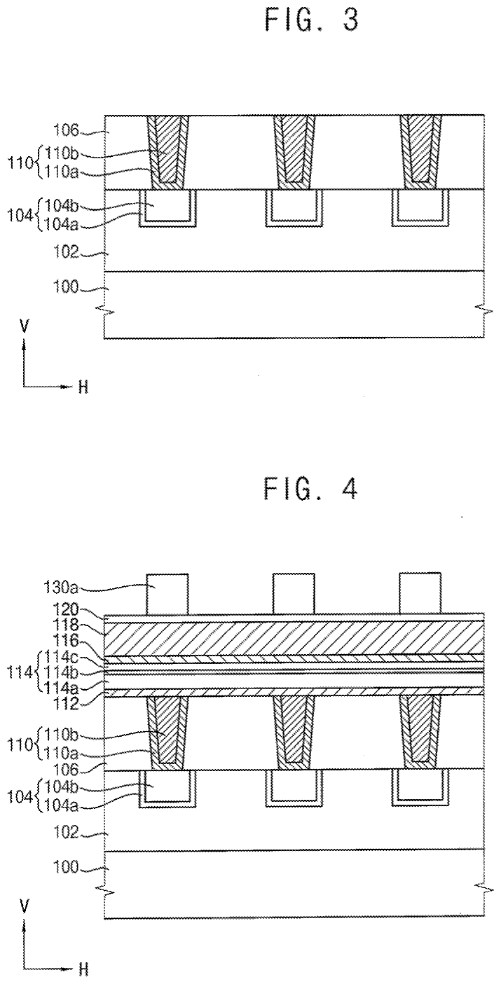

FIGS. 3 to 12 are cross-sectional views of stages in a method of manufacturing an MRAM device in accordance with example embodiments.

Referring to FIG. 3, circuit patterns may be formed on the substrate 100, and a lower insulating interlayer 102 may be formed to cover the circuit patterns.

A trench may be formed at an upper portion of the lower insulating interlayer 102, and a lower wiring 104 may be formed in the trench. The lower wiring 104 may include a metal.

A first insulating interlayer 106 may be formed on the lower insulating interlayer 102 and the lower wiring 104. A lower electrode contact 110 may be formed to pass through the first insulating interlayer 106. The lower electrode contact 110 may contact the lower wiring 104.

In an implementation, an etch stop layer may be further formed between the lower insulating interlayer 102 and the first insulating interlayer 106.

For forming the lower electrode contact 110, an etching mask may be formed on the first insulating interlayer 106, and the first insulating interlayer 106 may be dry-etched using the etching mask to form a contact hole. The dry etching process may be performed by a chemical etching process such as a reactive ion etching process.

A first barrier layer may be formed on surfaces of the contact hole and the first insulating interlayer 106. A first conductive layer may be formed on the first barrier layer to fill the contact hole. Thereafter, the first barrier layer and the first conductive layer may be planarized until an upper surface of the first insulating interlayer 106 is exposed to form the lower electrode contact 110 filling the contact hole. The lower electrode contact 110 may include the first barrier pattern 110a and the first conductive pattern 110b.

Referring to FIG. 4, a lower electrode layer 112, an MTJ layer 114, and a middle electrode layer 116 may be sequentially formed on the first insulating interlayer 106 and the lower electrode contact 110. An upper electrode layer 118 and an adhesion layer 120 may be sequentially formed on the middle electrode layer 116. A mask pattern 130a may be formed on the adhesion layer 120.

The MTJ layer 114 may include a first magnetic layer 114a, a tunnel barrier layer 114b, and a second magnetic layer 114c sequentially stacked.

In an implementation, the middle electrode layer 116 may not be formed.

The adhesion layer 120 may facilitate attaching of the mask pattern 130a on an upper surface of the adhesion layer 120. In an implementation, the adhesion layer 120 may include a nitride such as silicon nitride, silicon oxynitride, or the like.

The mask pattern 130a may face, overlie, or be aligned with the lower electrode contact 110. The mask pattern 130a may have a pillar shape. In an implementation, a plurality of mask patterns 130a may be regularly arranged. In an implementation, the mask pattern 130a may include silicon oxide.

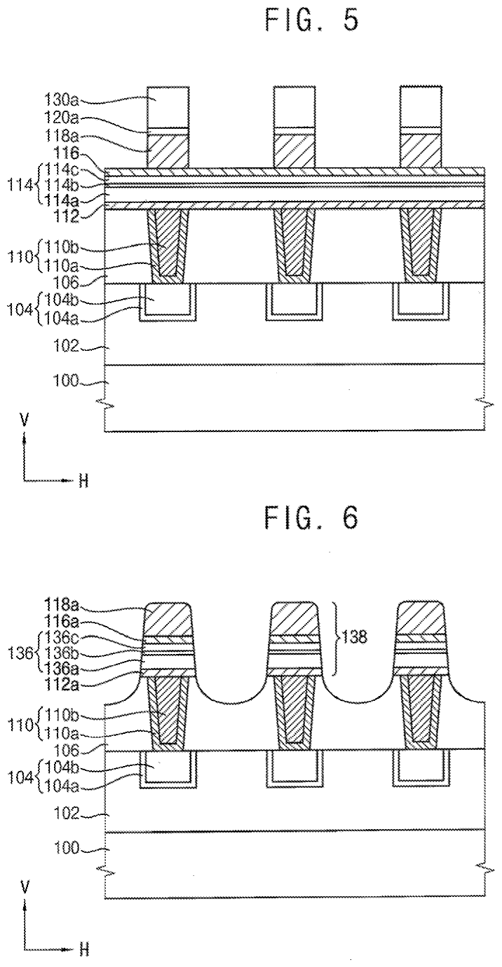

Referring to FIG. 5, the adhesion layer 120 and the upper electrode layer 118 may be anisotropically etched using the mask pattern 130a as an etching mask. The anisotropic etching process may include a reactive ion etching (RIE) process. When the etching process is performed, an upper electrode 118a and an adhesion layer pattern 120a may be formed on the middle electrode layer 116.

In an implementation, all or part of the mask pattern 130a may be removed during the etching process.

Referring to FIG. 6, the middle electrode layer 116, the MTJ layer 114, and the lower electrode layer 112 may be sequentially etched using a stacked structure including the upper electrode 118a, the adhesion layer pattern 120a, and the mask pattern 130a as an etching mask. Subsequently, an upper portion of the first insulating interlayer 106 may be partially etched by over-etching.

By the etching process, a first structure 138 including a lower electrode 112a, an MTJ structure 136, a middle electrode 116a, and the upper electrode 118a sequentially stacked may be formed on the first insulating interlayer 106. In an implementation, a recess may be formed on an upper surface of the first insulating interlayer 106 between the first structures 138.

The first structure 138 may contact the lower electrode contact 110, and may have a pillar shape. The MTJ structure 136 may include a first magnetic pattern 136a, a tunnel barrier pattern 136b, and a second magnetic pattern 136c sequentially stacked.

In an implementation, a sidewall of the first structure 138 may be inclined such that a width of the first structure 138 decreases downwardly (e.g., with increasing proximity to the substrate 100 in the vertical direction V). In an implementation, the sidewall of the first structure 138 may have a vertical slope (e.g., the first structure 138 may have a constant width along its height in the vertical direction V).

In the etching process, the mask pattern 130a and the adhesion layer pattern 120a may be completely removed. In an implementation, an upper portion of the upper electrode 118a may be partially etched.

The upper portion of the first insulating interlayer 106 may be partially etched by the etching process, and defects in which the first structures 138 are not separated from each other may be decreased. When the etching process is performed, the upper surface of the first insulating interlayer 106 between the first structures 138 may be lower than a lower surface of the first structure 138.

The etching process may include a physical etching process such as an ion beam etching (IBE) process. In an implementation, the etching process may include, e.g., argon ion sputtering process. In an implementation, incident angles of ion beams used as an etching source may be changed at least once during the etching process.

In an implementation, a first etching process for etching the middle electrode layer 116, the MTJ layer 114, and the lower electrode layer 112 may be performed. The middle electrode layer 116, the MTJ layer 114, and the lower electrode layer 112 may be separated by the first etching process. In the first etching process, the ion beam may be incident at a high angle, e.g., higher than 70 degrees, with respect to the upper surface of the substrate 100. When the first etching process is preformed, sputtered metallic materials may be redeposited on a sidewall of a patterned structure. After the first etching process, a second etching process for removing the redeposited metallic material may be further performed. In an implementation, in the second etching process, the ion beam may be incident at a low angle, e.g., 70 degrees or less with respect to the upper surface of the substrate 100.

As such, in each of the first and second etching processes, the ion beam having an incident angle with respect to the upper surface of the substrate 100 may be supplied on upper surfaces of exposed layers.

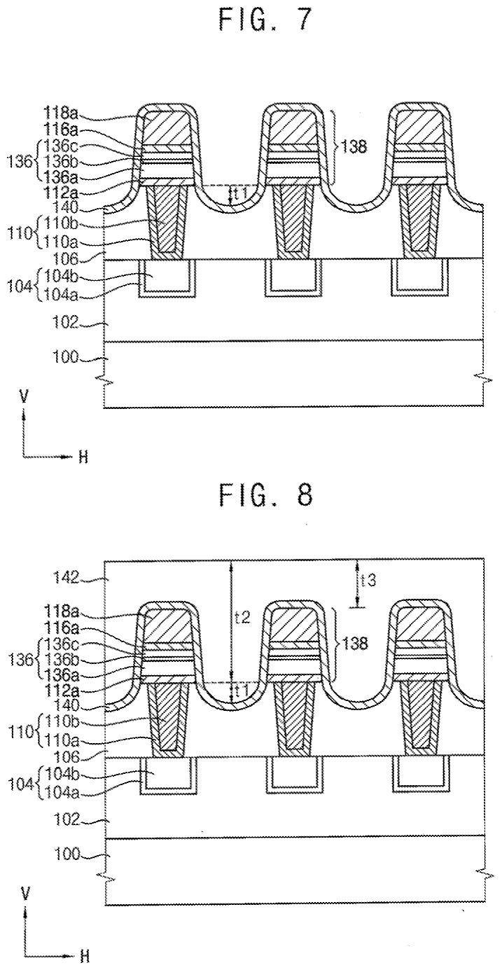

Referring to FIG. 7, a capping layer 140 may be conformally formed on surfaces of the first structure 138 and the first insulating interlayer 106. The capping layer 140 may cover upper surfaces of the first structure 138 and the first insulating interlayer 106.

In an implementation, the capping layer 140 may be formed to have a uniform thickness. The capping layer 140 may help protect a sidewall of the MTJ structure 136 in the first structure 138.

In an implementation, the capping layer 140 may be formed by an atomic layer deposition (ALD) process or a chemical vapor deposition (CVD) process. The capping layer 140 may include, e.g., silicon nitride.

In an implementation, an upper surface of the capping layer 140 formed on the first insulating interlayer 106 may be lower (e.g., closer to the substrate 100 in the vertical direction V) than a plane of the lower surface of the first structure 138 (e.g., the plane being represented by a dashed line in FIG. 7), and thus the upper surface of the capping layer 140 may include a recess. In an implementation, the recess of the upper surface of the capping layer 140 may be formed by the recess of the upper surface of the first insulating interlayer 106. A height (in the vertical direction V) from a lowermost portion or point of an upper surface of the capping layer 140 to the plane of the lower surface of the first structure 138 may be a first height t1.

Referring to FIG. 8, a second insulating interlayer 142 may be formed on the capping layer 140. The second insulating interlayer 142 may be formed to fill a space between the first structures 138. The second insulating interlayer 142 may include an oxide such as silicon oxide. The second insulating interlayer 142 may have a first dielectric constant.

The second insulating interlayer 142 may be formed by a deposition process having excellent gap fill property. Also, the deposition process may be process for forming a layer having a flat upper surface regardless of a lower structure. In addition, during the forming the second insulating interlayer 142, characteristics of the MTJ structure 136 may not be changed. In an implementation, the deposition process for forming the second insulating interlayer 142 may be performed at a temperature of about 500° C. or less, e.g. about 400° C. or less.

In an implementation, the second insulating interlayer 142 may include a silicon oxide layer formed by an HDP-CVD process. In the HDP-CVD process, a deposition layer may be formed by repeatedly performing deposition and some etching processes. In the etching during the HDP process, a protruding portion of the deposition layer may be partially etched to be flatten an upper surface of the deposition layer. In an implementation, when the deposition layer is deposited to a target thickness or more, the upper surface of the deposition layer may have high flatness.

In an implementation, a height t2 (in the vertical direction V) from the plane of the lower surface of the first structure 138 to the upper surface of the second insulating interlayer 142 may be greater than twice the first height t1.

In an implementation, the upper surface of the second insulating interlayer 142 may be higher than the upper surface of the first structure 138 (e.g., the upper surface of the second insulating interlayer 142 may be farther from the substrate 100 in the vertical direction than the upper surface of the first structure 138 is to the substrate 100).

The upper surface of the second insulating interlayer 142 may be formed to be flat, and a planarization process may not be performed.

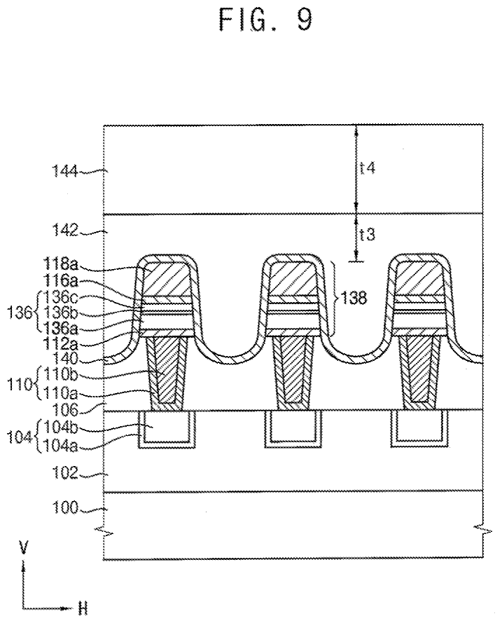

Referring to FIG. 9, a third insulating interlayer 144 directly contacting the second insulating interlayer 142 may be formed on the second insulating interlayer 142.

The third insulating interlayer 144 may include an oxide formed by a deposition process different from the deposition process for forming the second insulating interlayer 142.

In an implementation, the third insulating interlayer 144 may include a low dielectric layer. The third insulating interlayer 144 may have a second dielectric constant lower than the first dielectric constant.

In an implementation, the third insulating interlayer 144 may include silicon oxide, fluorinated silicon oxide (SiOF), carbon doped oxide, or the like. In an implementation, the third insulating interlayer 144 may include a porous oxide.

In an implementation, the third insulating interlayer 144 may be formed by stacking a plurality of low dielectric layers.

The third insulating interlayer 144 may have a dielectric constant lower than that of the second insulating interlayer 142. In an implementation, when a height of the third insulating interlayer 144 relatively increases, a parasitic capacitance between bit lines subsequently formed may be decreased.

In an implementation, a height t4 (in the vertical direction V) of the third insulating interlayer 144 may be higher than a height t3 of the portion of the second insulating interlayer 142 positioned on or above a plane of the top surface of the first structure 138. In an implementation, an effect of reducing the parasitic capacitance may be increased.

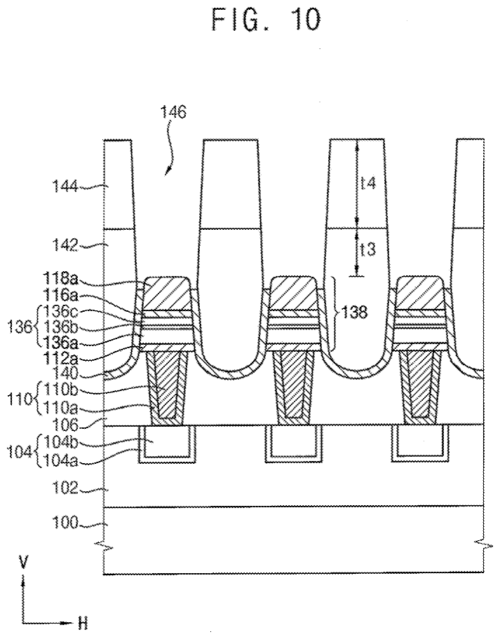

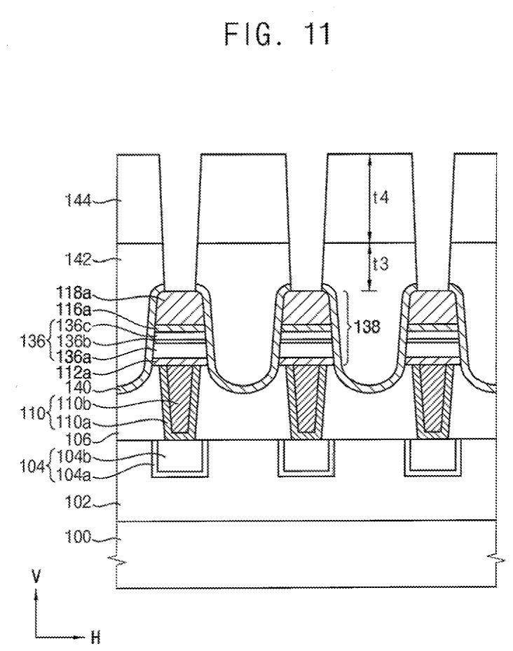

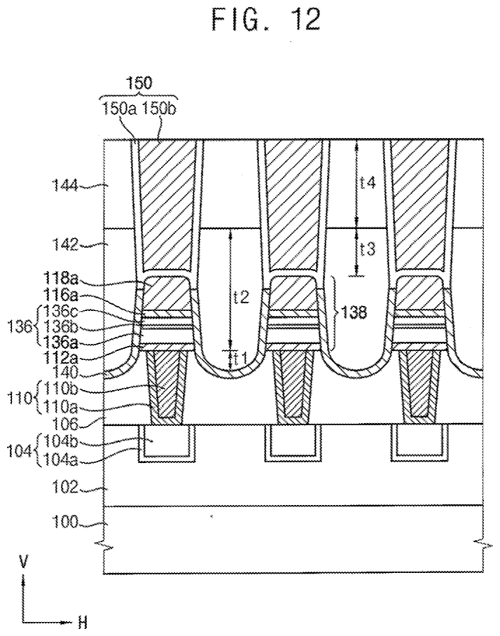

Referring to FIG. 10, the third insulating interlayer 144, the second insulating interlayer 142, and the capping layer 140 may be etched to form a trench 146 exposing the upper electrode 118a.

The trench 146 may have a line shape extending in a direction parallel to an upper surface of the substrate 100. A plurality of upper electrodes 118a arranged in the direction parallel to an upper surface of the substrate 100 may be exposed by or at a bottom of the trench 146.

In an implementation, a lower width of the trench 146 may be greater than a top width of the upper electrode 118a (as measured in the horizontal direction H). In this case, in the process of forming the trench 146, the upper surface of the upper electrode 118a and the capping layer 140 formed on an upper sidewall of the upper electrode 118a may be removed. In an implementation, the upper surface and an upper sidewall of the upper electrode 118a may be exposed at the bottom of the trench 146. In an implementation, an upper portion of the upper electrode 118a may protrude from or at the bottom of the trench 146.

In an implementation, referring to FIG. 11, the lower width of the trench 146 may be equal to or less than the top width of the upper electrode 118a. In this case, in the process for forming the trench 146, the capping layer 140 formed on the upper surface of the upper electrode 118a may be removed. Thus, the upper surface of the upper electrode 118a may be exposed by the bottom of the trench 146. When the trench 146 shown in FIG. 11 is formed, the MRAM device shown in FIG. 2 may be manufactured by subsequent processes for forming a bit line.

Referring to FIG. 12, a bit line 150 may be formed in the trench 146. The bit line 150 may include a second barrier pattern 150a and a second metal pattern 150b.

In an implementation, the bit line 150 may contact the upper surface and the sidewall of the upper electrode 118a. A lowermost surface of the bit line 150 may be lower than the upper surface of the upper electrode 118a. Thus, the upper electrode 118a may protrude from or higher than the lowermost surface of the bit line 150.

In an implementation, a lower width of the bit line 150 may be greater than the top width of the upper electrode 118a.

As such, an insulation material having a dielectric constant higher than that of silicon oxide, e.g., silicon nitride, may not be formed between the bit lines 150. Also, a low dielectric layer may be formed between the bit lines 150, so that a parasitic capacitance between the bit lines 150 may be decreased.

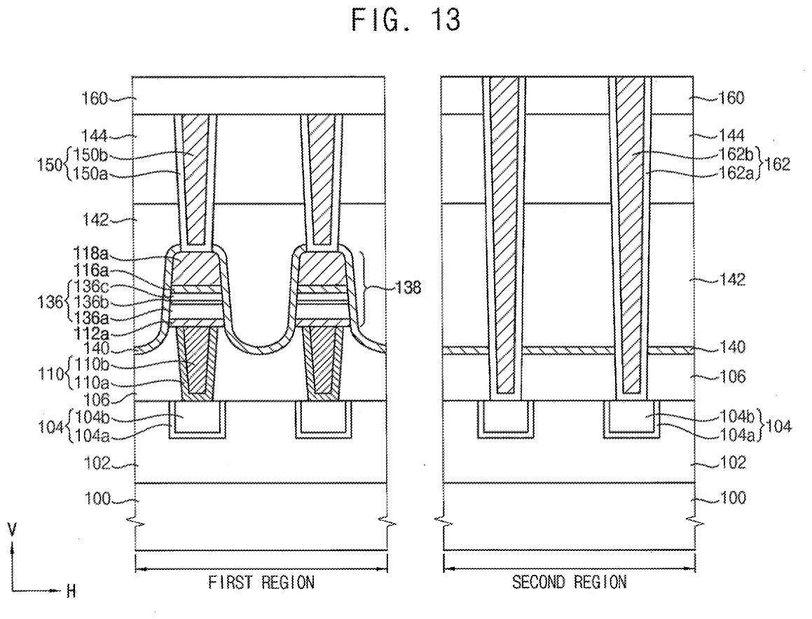

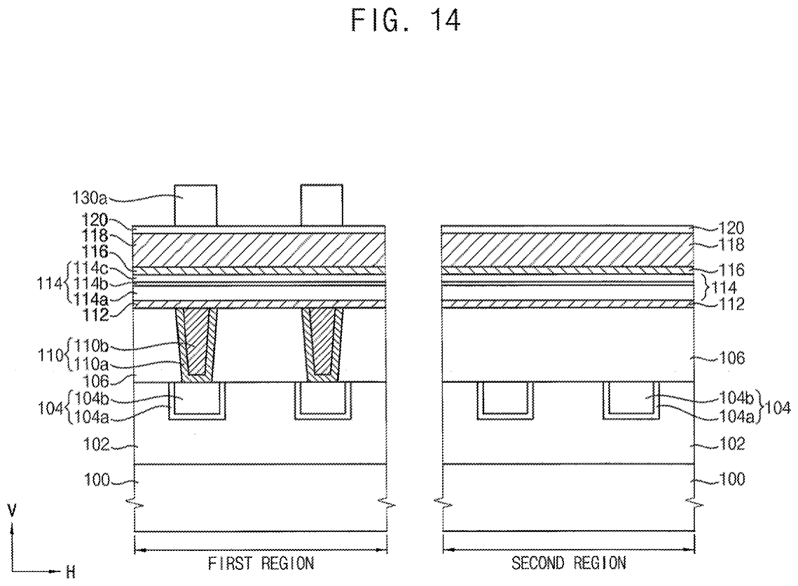

FIG. 13 is a cross-sectional view of an embedded device including an MRAM device and a logic device in accordance with example embodiments.

Referring to FIG. 13, the substrate 100 may include a first region on which a resistive memory is formed and a second region on which logic circuits are formed.

An MRAM device may be formed on the first region of the substrate 100. In an implementation, the MRAM device shown in FIG. 2 may be formed on the first region of the substrate 100. In an implementation, the MRAM device shown in FIG. 1 may be formed on the first region of the substrate 100.

Circuit patterns constituting a logic device may be on the second region of the substrate 100.

In an implementation, some elements formed on the first region of the substrate may be identically formed on the second region of the substrate 100. In an implementation, the lower insulating interlayer 102, the lower wiring 104, the first insulating interlayer 106, the capping layer 140, the second insulating interlayer 142, and the third insulating interlayer 144 may be formed on the second region of the substrate 100. The lower insulating interlayer 102, the lower wiring 104, the first insulating interlayer 106, the capping layer 140, the second insulating interlayer 142, and the third insulating interlayer 144 may be substantially the same as those illustrated with reference to FIG. 1, respectively.

The logic device may be formed on the second region of the substrate 100, and the lower electrode contact 110 and the first structure 138 may not be included in the second region. In an implementation, upper surfaces of the capping layer 140, the second insulating interlayer 142 and the third insulating interlayer 144 may be substantially flat. In an implementation, the bit line 150 may not be formed on the second region of the substrate 100.

A fourth insulating interlayer 160 may be formed on the third insulating interlayer 144 and the bit line 150 on the first and second regions of the substrate 100. The fourth insulating interlayer 160 may include silicon oxide.

On the second regions of the substrate 100, a via contact 162 may pass through the fourth insulating interlayer 160, the third insulating interlayer 144, the second insulating interlayer 142, the capping layer 140, and the first insulating interlayer 106. The via contact 162 may contact the lower wiring 104. In an implementation, upper wirings may be further formed on the via contact 162.

On the second regions of the substrate 100, the second insulating interlayer 142, the third insulating interlayer 144, and the fourth insulating interlayer 160 may be on the capping layer 140. The insulation layers on the capping layer 140 may have a dielectric constant lower than that of silicon nitride. In an implementation, an etch stop layer including silicon nitride may not be formed between the second insulating interlayer 142 and the third insulating interlayer 144.

An insulation material having a dielectric constant higher than that of silicon oxide may not be formed between the via contacts 162 and between the bit lines 150 on the capping layer 140. Further, the third insulating interlayer 144 having a low dielectric constant may be between the via contacts 162 and between the bit lines 150. Thus, a parasitic capacitance between the via contacts 162 and a parasitic capacitance of the bit line 150 may be decreased. Therefore, operating characteristics of the MRAM device and the logic device may be improved.

FIGS. 14 to 18 are cross-sectional views of stages in a method of manufacturing an embedded device including an MRAM device and a logic device in accordance with example embodiments.

Referring to FIG. 14, circuit patterns may be formed on a substrate 100 including a first region and a second region. The lower insulating interlayer 102 may be formed to cover the circuit patterns. The lower wirings 104 may be formed in the lower insulating interlayer 102.

The first insulating interlayer 106 may be formed on the lower insulating interlayer 102 and the lower wirings 104.

The lower electrode contact 110 may be formed through the first insulating interlayer 106 on the first region of the substrate 100. Thus, the lower electrode contact 110 may be formed only on the first region of the substrate 100.

The lower electrode contact 110 may contact the lower wiring 104. In an implementation, an etch stop layer may be further formed between the lower insulating interlayer 102 and the first insulating interlayer 106.

Thereafter, the lower electrode layer 112, the MTJ layer 114, and the middle electrode layer 116 may be sequentially formed on the first insulating interlayer 106 and the lower electrode contact 110. The upper electrode layer 118 and the adhesion layer 120 may be sequentially formed on the middle electrode layer 116. A mask pattern 130a may be formed on the adhesion layer 120.

The mask pattern 130a may face or be aligned with the lower electrode contact 110. In an implementation, the mask pattern 130a may be formed only on the first region of the substrate 100.

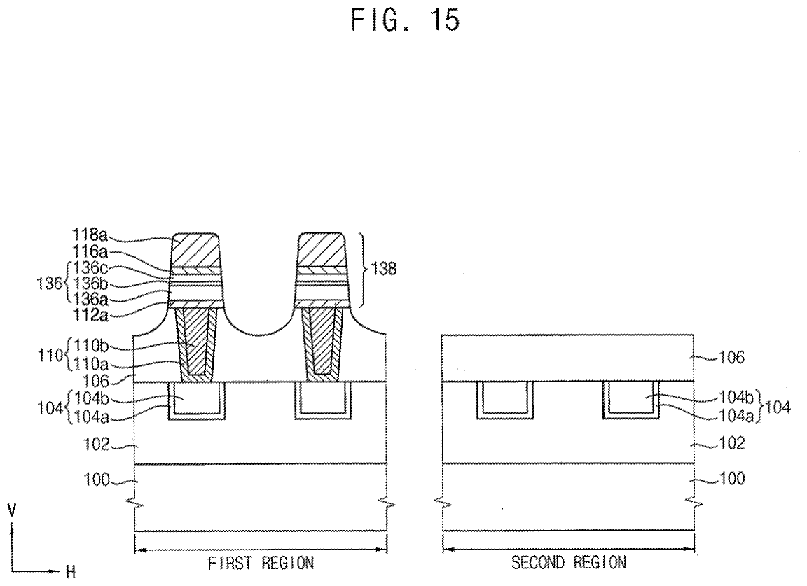

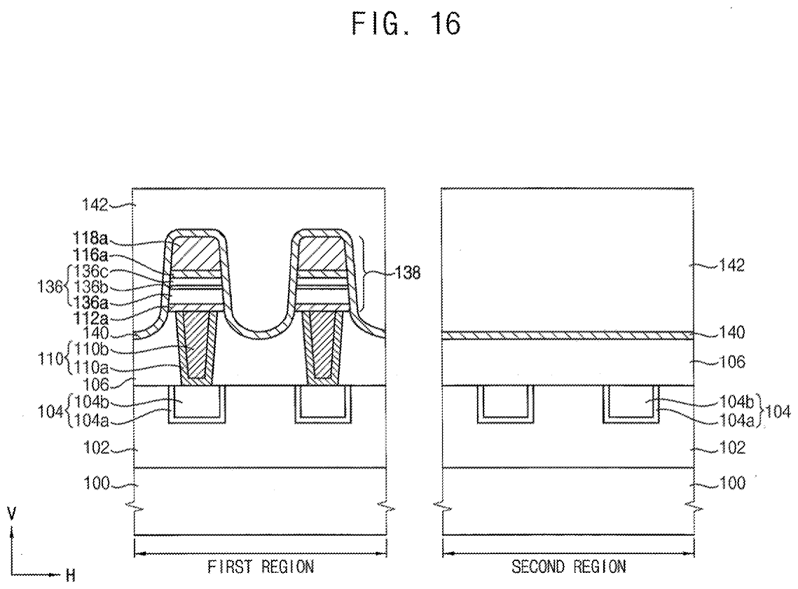

Referring to FIG. 15, the adhesion layer 120 and the upper electrode layer 118 may be anisotropically etched using the mask pattern 130a as an etching mask to form the adhesion layer pattern and the upper electrode 118a. The middle electrode layer 116, the MTJ layer 114, and the lower electrode layer 112 may be sequentially etched using a stacked structure including the upper electrode 118a, the adhesion layer pattern and the mask pattern as an etching mask. Further, an upper portion of the first insulating interlayer 106 may be etched by over-etching. The etching process may be substantially the same as illustrated with reference to FIGS. 5 and 6.

By performing the etching process, the first structure 138 including the sequentially stacked lower electrode 112a, MTJ structure 136, middle electrode 116a, and upper electrode 118a may be formed on the first insulating interlayer 106 and the lower electrode contact 110 on the first region of the substrate 100.

The middle electrode layer 116, the MTJ layer 114, and the lower electrode layer 112 on the second region of the substrate 100 may be removed. In an implementation, on the second region of the substrate 100, the upper surface of the first insulating interlayer 106 may be exposed.

In the etching process, the upper portion of the first insulating interlayer 106 may be partially etched, and defects in which the first structures 138 are not separated from each other may be decreased. After the etching process, on the first region of the substrate 100, the upper surface of the first insulating interlayer 106 between the first structures 138 may be lower than the plane of the lower surface of the first structure 138. Thus, a recess may be formed on the upper surface of the first insulating interlayer 106 between the first structures 138. In addition, on the second region of the substrate 100, the upper surface of the first insulating interlayer 106 may be substantially flat.

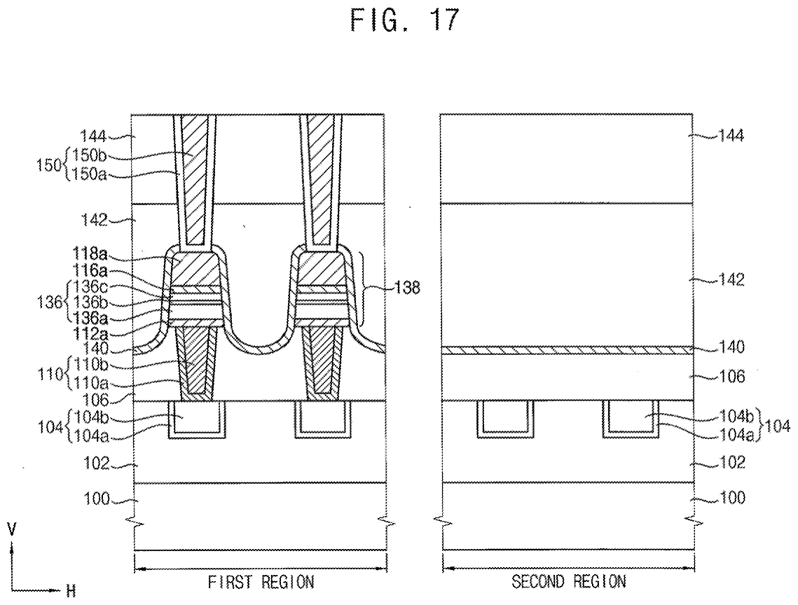

Referring to FIG. 16, the capping layer 140 may be conformally formed on the surfaces of the first structure 138 and the first insulating interlayer 106. The capping layer 140 may cover the upper surfaces of the first structure 138 and the first insulating interlayer 106.

In an implementation, an upper surface of the capping layer 140 on the first insulating interlayer 106 in the first region of the substrate 100 may be lower than the plane of the lower surface of the first structure 138, and thus the upper surface of the capping layer 140 may include a recess. A height from a lowermost portion of the upper surface of the capping layer 140 to the plane of the lower surface of the first structure 138 may be a first height t1. In an implementation, the upper surface of the capping layer 140 formed on the second region of the substrate 100 may be substantially flat.

The second insulating interlayer 142 may be formed on the capping layer 140. The second insulating interlayer 142 may be formed to fill a space between the first structures 138. The second insulating interlayer 142 may include an oxide such as silicon oxide. The second insulating interlayer 142 may have a first dielectric constant.

The processes for forming the capping layer 140 and the second insulating interlayer 142 may be substantially the same as processes illustrated with reference to FIGS. 7 and 8.

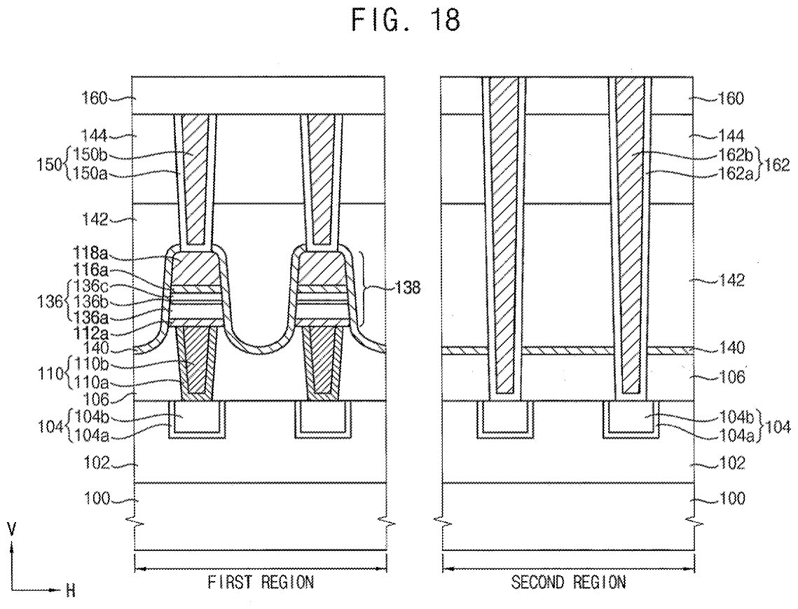

Referring to FIG. 17, the third insulating interlayer 144 may be formed directly on the second insulating interlayer 142. The third insulating interlayer 144 may include an oxide formed by a deposition process different from the deposition process for forming the second insulating interlayer 142.

In an implementation, the third insulating interlayer 144 may include a low dielectric layer. The third insulating interlayer 144 may have a second dielectric constant lower than the first dielectric constant.

The process for forming the third insulating interlayer 144 may be substantially the same as the process illustrated with reference to FIG. 9.

The third insulating interlayer 144, the second insulating interlayer 142 and the capping layer 140 may be etched to form a trench exposing the upper surface of the upper electrode 118a. The bit line 150 may be formed in the trench. The bit line 150 may include the second barrier pattern 150a and the second metal pattern 150b.

In an implementation, the process for forming the trench may be substantially the same as the process illustrated with reference to FIG. 11. In this case, the MRAM as shown in FIG. 2 may be formed on the first region of the substrate 100 by subsequent processes.

In an implementation, the process for forming the trench may be substantially the same as the process illustrated with reference to FIG. 10. In this case, the MRAM device as shown in FIG. 1 may be formed on the first region of the substrate 100 by subsequent processes.

Referring to FIG. 18, a fourth insulating interlayer 160 may be formed on the third insulating interlayer 144. Thereafter, the fourth insulating interlayer 160, the third insulating interlayer 144, the second insulating interlayer 142, the capping layer 140, and the first insulating interlayer 106 on the second region of the substrate 100 may be etched to form a via hole exposing the lower wiring 104. A via contact 162 may be formed in the via hole.

To form the via contact 162, a barrier layer may be formed on surfaces of the via hole and the fourth insulating interlayer 160, and a metal layer may be formed on the barrier layer to fill the via hole. Thereafter, the barrier layer and the metal layer may be planarized until the surface of the fourth insulating interlayer 160 is exposed to form the via contact 162 in the via hole. Thus, the via contact 162 may include a third barrier pattern 162a and a third metal pattern 162b.

By way of summation and review, an MRAM device may be highly integrated, and a parasitic capacitance between the bit lines could be increased. Thus, operating characteristics of some MRAM devices could be degraded.

One or more embodiments may provide an MRAM device having excellent operating characteristics.

One or more embodiments may provide an embedded device having excellent operating characteristics.

In the MRAM device, a parasitic capacitance between the bit lines may be decreased. Thus, the MRAM device may have excellent electrical characteristics.

As described above, an embedded device including an MRAM device and a logic device may be manufactured. In the embedded device, an insulating material having a dielectric constant higher than that of silicon oxide may not be included between the via contacts 162 and between the bit lines 150 on the capping layer 140. Thus, parasitic capacitances between the via contacts 162 and between the bit lines 150 may be decreased.

The MRAM device may be used as a memory included in electronic products such as mobile devices, memory cards, and computers.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A magnetoresistive random access memory device, comprising:
a first insulating interlayer on a substrate;
lower electrode contacts passing through the first insulating interlayer;
first structures on the lower electrode contacts, respectively, each of the first structures including a stacked lower electrode, magnetic tunnel junction (MTJ) structure, and upper electrode;
a second insulating interlayer on the first structures and the first insulating interlayer, the second insulating interlayer filling a space between the first structures;
a third insulating interlayer directly contacting the second insulating interlayer, the third insulating interlayer having a dielectric constant lower than a dielectric constant of the second insulating interlayer; and
a bit line passing through the third insulating interlayer and the second insulating interlayer, the bit line contacting the upper electrode of each of the first structures.

2. The magnetoresistive random access memory device as claimed in claim 1, wherein an upper surface of the first insulating interlayer between the first structures includes a recess, surfaces of the recess being closer to the substrate in a vertical direction than a plane of lower surfaces of the first structures is to the substrate in the vertical direction.

3. The magnetoresistive random access memory device as claimed in claim 2, wherein a height from the plane of the lower surfaces of the first structures to an upper surface of the second insulating interlayer in the vertical direction is greater than twice a height from a lowermost point of the recess of the first insulating interlayer to the plane of the lower surfaces of the first structures in the vertical direction.

4. The magnetoresistive random access memory device as claimed in claim 1, wherein:
the second insulating interlayer includes an oxide formed by one deposition process, and
the third insulating interlayer includes an oxide formed by another deposition process, the other deposition process being different from the one deposition process.

5. The magnetoresistive random access memory device as claimed in claim 1, wherein the second insulating interlayer includes a silicon oxide formed by an HDP-CVD process.

6. The magnetoresistive random access memory device as claimed in claim 1, wherein the third insulating interlayer includes a silicon oxide, a fluorinated silicon oxide (SiOF), or a carbon doped oxide.

7. The magnetoresistive random access memory device as claimed in claim 1, wherein a height of the third insulating interlayer in a vertical direction is greater than a height of a portion of the second insulating interlayer positioned between a plane of top surfaces of the first structures and the third insulating interlayer in the vertical direction.

8. The magnetoresistive random access memory device as claimed in claim 1, further comprising a capping layer covering an upper surface of the first insulating interlayer and surfaces of the first structures.

9. The magnetoresistive random access memory device as claimed in claim 8, wherein the capping layer includes silicon nitride or silicon oxynitride.

10. The magnetoresistive random access memory device as claimed in claim 1, wherein the bit line includes a metal.

11. A magnetoresistive random access memory device, comprising:
a lower insulating interlayer and a lower wiring on a substrate;
a first insulating interlayer on the lower insulating interlayer and the lower wiring;
lower electrode contacts passing through the first insulating interlayer;
first structures on the lower electrode contacts, respectively, each of the first structures including a stacked lower electrode, magnetic tunnel junction (MTJ) structure, and upper electrode stacked;
a capping layer covering an upper surface of the first insulating interlayer and surfaces of the first structures;
a second insulating interlayer on the capping layer, the second insulating interlayer including an oxide and filling a space between the first structures;
a third insulating interlayer directly contacting the second insulating interlayer, the third insulating interlayer including an oxide having a dielectric constant lower than that of the second insulating interlayer; and
a bit line passing through the third insulating interlayer, the second insulating interlayer, and the capping layer, the bit line contacting the upper electrode of each of the first structures;
wherein the upper surface of the first insulating interlayer between the first structures includes a recess, surfaces of the recess being closer to the substrate in a vertical direction than a plane of lower surfaces of the first structures is to the substrate in the vertical direction.

12. The magnetoresistive random access memory device as claimed in claim 11, wherein a height from the plane of the lower surfaces of the first structures to an upper surface of the second insulating interlayer in the vertical direction is greater than twice a height from a lowermost point of the recess of the first insulating interlayer to the plane of the lower surfaces of the first structures in the vertical direction.

13. The magnetoresistive random access memory device as claimed in claim 11, wherein:
the second insulating interlayer includes an oxide formed by one deposition process, and
the third insulating interlayer includes an oxide formed by another deposition process, the other deposition process being different from the one deposition process.

14. The magnetoresistive random access memory device as claimed in claim 11, wherein a height of the third insulating interlayer in the vertical direction is greater than a height of a portion of the second insulating interlayer positioned between a plane of top surfaces of the first structures and the third insulating interlayer in the vertical direction.

15. An embedded device, comprising:
a substrate including a first region and a second region;
a first insulating interlayer on the substrate;
lower electrode contacts passing through the first insulating interlayer on the first region;
first structures on the lower electrode contacts, respectively, each of the first structures including a stacked lower electrode, magnetic tunnel junction (MTJ) structure, and upper electrode;
a capping layer covering an upper surface of the first insulating interlayer and surfaces of the first structures on the first region and the second region;
a second insulating interlayer on the capping layer, the second insulating interlayer including an oxide and filling a space between the first structures;
a third insulating interlayer directly contacting the second insulating interlayer, the third insulating interlayer including an oxide having a dielectric constant lower than that of the second insulating interlayer;
a bit line passing through the third insulating interlayer and the second insulating interlayer on the first region, the bit line contacting the upper electrode of each of the first structures; and
a via contact passing through the third insulating interlayer, the second insulating interlayer, the capping layer, and the first insulating interlayer on the second region.

16. The embedded device as claimed in claim 15, wherein:
the second insulating interlayer includes an oxide formed by one deposition process, and
the third insulating interlayer includes an oxide formed by another deposition process, the other deposition process being different from the one deposition process.

17. The embedded device as claimed in claim 15, wherein the second insulating interlayer includes a silicon oxide formed by an HDP-CVD process.

18. The embedded device as claimed in claim 15, wherein a height of the third insulating interlayer in a vertical direction is greater than a height of a portion of the second insulating interlayer positioned between a plane of top surfaces of the first structures and the third insulating interlayer in the vertical direction.

19. The embedded device as claimed in claim 15, wherein an upper surface of the first insulating interlayer between the first structures includes a recess, surfaces of the recess being closer to the substrate in a vertical direction than a plane of lower surfaces of the first structures is to the substrate in the vertical direction.

20. The embedded device as claimed in claim 15, wherein each of the bit line and the via contact includes a metal.
